(19) United States
(12) Patent Application Publication
(10) Pub. No.: US 2021/0091274 A1
(43) Pub. Date: Mar. 25, 2021

(54) WAVELENGTH CONVERSION MEMBER AND LIGHT EMITTING DEVICE

(71) Applicant: NIPPON ELECTRIC GLASS CO., LTD., Otsu-shi, Shiga (JP)

(72) Inventors: Hiroyuki SHIMIZU, Otsu-shi (JP); Hideki ASANO, Otsu-shi (JP); Minekazu TAKADA, Otsu-shi (JP); Takashi MURATA, Otsu-shi (JP)

(21) Appl. No.: 16/629,578

(22) PCT Filed: Jul. 12, 2018
(86) PCT No.: PCT/JP2018/026353

§ 371 Date: Jan. 9, 2020

(30) Foreign Application Priority Data
Jul. 27, 2017 (JP) 2017-145157
May 29, 2018 (JP) 2018-101969

(51) Int. Cl. H01L 33/50; H01L 33/60

(52) U.S. Cl. CPC H01L 33/505; H01L 2933/0091; H01L 33/60; H01L 33/502

(57) ABSTRACT

Provided are a wavelength conversion member having high light extraction efficiency and excellent luminescence intensity and a light emitting device using the wavelength conversion member. A wavelength conversion member 1 containing a phosphor and having a plate-like shape includes a light entrance surface 1a and a light exit surface 1b opposite to the light entrance surface 1a, wherein Raᵢₙ is 0.01 to 0.05 μm and Raₒᵤₜ−Raᵢₙ is 0.01 to 0.2 μm where Raᵢₙ represents a surface roughness of the light entrance surface la and Raₒᵤₜ represents a surface roughness of the light exit surface 1b.

### TECHNICAL FIELD

The present invention relates to wavelength conversion members for converting the wavelength of light emitted from a light emitting diode (LED), a laser diode (LD) or the like to a different wavelength and light emitting devices using the same.

### BACKGROUND ART

Recently, attention has been increasingly focused on light emitting devices and the like using LEDs or LDs, as next-generation light sources to replace fluorescence lamps and incandescent lamps. As an example of such a next-generation light source, there is a disclosure of a light emitting device in which an LED for emitting a blue light is combined with a wavelength conversion member capable of absorbing part of the light from the LED to convert it to a yellow light. This light emitting device emits a white light which is a synthesized light of the blue light emitted from the LED and the yellow light emitted from the wavelength conversion member. Patent Literature 1 proposes, as an example of a wavelength conversion member, a wavelength conversion member in which inorganic phosphor powder is dispersed in a glass matrix.

### CITATION LIST

### Patent Literature

[PTL 1]

JP-A-2003-258308

### SUMMARY OF INVENTION

### Technical Problem

The above wavelength conversion member has a problem of less light extraction efficiency and thus difficulty in providing sufficient luminescence intensity.

Therefore, the present invention has the object of proposing a wavelength conversion member having high light extraction efficiency and excellent luminescence intensity and a light emitting device using the wavelength conversion member.

### Solution to Problem

The inventors conducted intensive studies and, as a result, found that restriction of the surface roughnesses of the light entrance surface and light exit surface of a wavelength conversion member within respective specified ranges enables an increase in light extraction efficiency and thus enables provision of a wavelength conversion member having excellent luminescence intensity.

Specifically, a wavelength conversion member according to the present invention is a wavelength conversion member containing a phosphor and having a plate-like shape and includes a light entrance surface and a light exit surface opposite to the light entrance surface, wherein Raᵢₙ is 0.01 to 0.05 μm and Raₒᵤₜ−Raᵢₙ is 0.01 to 0.2 μm where Raᵢₙ represents a surface roughness of the light entrance surface and Raₒᵤₜ represents a surface roughness of the light exit surface.

In the wavelength conversion member according to the present invention, the surface roughness Raₒᵤₜ of the light exit surface is preferably 0.06 μm or more. By doing so, the light extraction efficiency can be further increased.

The wavelength conversion member according to the present invention is preferably formed so that powder of the phosphor is dispersed in a glass matrix.

The wavelength conversion member according to the present invention preferably has a thickness of 0.01 to 1 mm.

A light emitting device according to the present invention includes the above-described wavelength conversion member and a light-emitting element capable of irradiating the wavelength conversion member with excitation light.

In the light emitting device according to the present invention, the light entrance surface of the wavelength conversion member and the light-emitting element are preferably bonded together by an adhesive layer.

In the light emitting device according to the present invention, a reflective layer is preferably disposed around the wavelength conversion member and the light-emitting element.

### Advantageous Effects of Invention

The present invention enables proposition of a wavelength conversion member having high light extraction efficiency and excellent luminescence intensity and a light emitting device using the wavelength conversion member.

### BRIEF DESCRIPTION OF DRAWINGS

FIG. 1 is a schematic cross-sectional view showing a wavelength conversion member according to an embodiment of the present invention.

FIG. 2 is a schematic cross-sectional view showing a light emitting device according to an embodiment of the present invention.

### DESCRIPTION OF EMBODIMENTS

Hereinafter, a description will be given of preferred embodiments. However, the following embodiments are merely illustrative and the present invention is not limited to the following embodiments. Throughout the drawings, members having substantially the same functions may be referred to by the same reference characters.

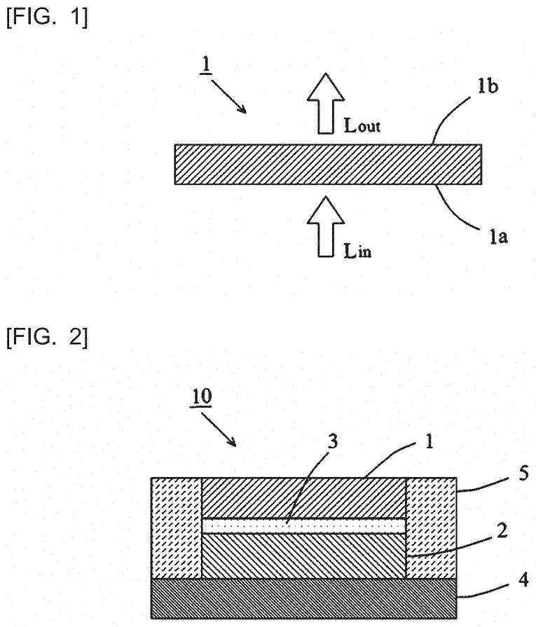

FIG. 1 is a schematic cross-sectional view showing a wavelength conversion member according to an embodiment of the present invention. The wavelength conversion member 1 has, for example, a rectangular plate-like shape. The wavelength conversion member 1 contains a phosphor and has a light entrance surface 1a and a light exit surface 1b opposite to the light entrance surface 1a. Excitation light for exciting the phosphor contained in the wavelength conversion member 1 is allowed to enter, as incident light Lᵢₙ, the wavelength conversion member 1 through the light entrance surface 1a. The incident light Lᵢₙ is converted in wavelength to fluorescence by the phosphor. A synthesized light of this fluorescence and incident light Liᵢₙ having not been converted in wavelength is emitted as outgoing light Lₒᵤₜ through the light exit surface 1b. For example, when the incident light Lᵢₙ is a blue light and the fluorescence is a yellow light, a synthesized light of the blue light and the yellow light is emitted as Lout.

With the surface roughness of the light entrance surface 1a of the wavelength conversion member 1 represented by Raᵢₙ and the surface roughness of the light exit surface 1b thereof represented by Raₒᵤₜ, it is satisfied that Raᵢₙ is 0.01 to 0.05 μm and Raₒᵤₜ−Raᵢₙ is 0.01 to 0.2 μm. By doing so, the light extraction efficiency can be increased. The reason for this can be assumed as follows. Since the surface roughness Raᵢₙ of the light entrance surface 1a is relatively small, the incident light Lᵢₙ is difficult to scatter on the light entrance surface 1a, so that the efficiency of light entering the inside of the wavelength conversion member 1 is increased. This can be attributed to the fact that the incident light Lᵢₙ, which is light emitted from an LED or an LD, generally has high straightness (directivity) and therefore has a high proportion of light component vertical to the light entrance surface 1a. Furthermore, since the surface roughness Raₒᵤₜ of the light exit surface 1b is large relative to Raᵢₙ, the light extraction efficiency of the outgoing light Lₒᵤₜ can be increased. The wavelength conversion member 1 is basically a light scatterer and, therefore, the incident light Lᵢₙ and fluorescence are scattered inside the wavelength conversion member 1 and thus oriented in all directions. Hence, if the surface roughness Raₒᵤₜ of the light exit surface 1b is small, the amount of light component exceeding the critical angle becomes large, so that the light extraction efficiency tends to be low. To avoid this, the surface roughness Raₒᵤₜ of the light exit surface 1b is set large enough, so that the effect of suppressing the reflection of scattered light can be increased.

If Raᵢₙ is too large, the incident light Lᵢₙ is scattered on the light entrance surface 1a, so that the efficiency of light entering the inside of the wavelength conversion member 1 tends to be low. As a result, the light extraction efficiency of the wavelength conversion member decreases, so that the luminescence intensity is likely to decrease. On the other hand, if Raᵢₙ is too small, the anchoring effect when the wavelength conversion member is bonded to a light-emitting element (to be described hereinafter) is difficult to obtain, so that the bonding strength is likely to decrease. Note that if the wavelength conversion member 1 is even partially peeled from the light-emitting element because of a decrease in bonding strength, an air layer having a low refractive index is formed between the wavelength conversion member 1 and the light-emitting element, so that the efficiency of incident light Lᵢₙ entering the wavelength conversion member 1 tends to significantly decrease. The preferred range of Raᵢₙ is 0.015 to 0.045 μm.

If Raₒᵤₜ−Raᵢₙ is too small, the outgoing light Lₒᵤₜ is easy to reflect on the light exit surface 1b, so that the light extraction efficiency is likely to decrease. On the other hand, if Raₒᵤₜ−Raᵢₙ is too large, the scattering of the outgoing light Lₒᵤₜ at the light exit surface 1b becomes large, so that the light extraction efficiency is likely to decrease instead. The preferred range of Raₒᵤₜ−Raᵢₙ is 0.02 to 0.18 μm and the more preferred range thereof is 0.05 to 0.17 μm.

Raₒᵤₜ is preferably not less than 0.06 μm, more preferably not less than 0.07 μm, particularly preferably not less than 0.08 μm, preferably not more than 0.25 μm, more preferably not more than 0.23 μm, and particularly preferably not more than 0.22 μm. If Raₒᵤₜ is too small, the outgoing light Lout is easy to reflect on the light exit surface 1b, so that the light extraction efficiency is likely to decrease. On the other hand, if Raₒᵤₜ is too large, the scattering of the outgoing light Lout at the light exit surface 1b becomes large, so that the light extraction efficiency is likely to decrease.

The wavelength conversion member 1 is made of, for example, a phosphor glass containing: a glass matrix; and a phosphor powder dispersed in the glass matrix.

No particular limitation is placed on the type of the glass matrix so long as it can be used as a dispersion medium for powder of a phosphor, such as an inorganic phosphor. For example, a borosilicate-based glass, a phosphate-based glass, a tin-phosphate-based glass, a bismuthate-based glass or a tellurite-based glass can be used. Examples of the borosilicate-based glass include those containing, in terms of % by mass, 30 to 85% SiO₂, 0 to 30% Al₂O₃, 0 to 50% B₂O₃, 0 to 10% Li₂O+Na₂O+K₂O, and 0 to 50% MgO+CaO+SrO+BaO. Examples of the tin-phosphate-based glass include those containing, in terms of % by mole, 30 to 90% SnO and 1 to 70% P₂O₅. Examples of the tellurite-based glass include those containing, in terms of % by mole, 50% or more TeO₂, 0 to 45% ZnO, 0 to 50% RO (where R represents at least one selected from Ca, Sr, and Ba), and 0 to 50% La₂O₃+Gd₂O₃+Y₂O₃.

The softening point of the glass matrix is preferably 250° C. to 1000° C., more preferably 300° C. to 950° C., and still more preferably in a range of 500° C. to 900° C. If the softening point of the glass matrix is too low, the mechanical strength and chemical durability of the wavelength conversion member 1 may decrease. In addition, since the thermal resistance of the glass matrix itself is low, the glass matrix may be softened and deformed by heat produced from the phosphor. On the other hand, if the softening point of the glass matrix is too high and in the case where the production process contains a firing step, the phosphor may degrade in the firing step, so that the luminescence intensity of the wavelength conversion member 1 may decrease. In addition, if the softening point of the glass matrix is high, the firing temperature also becomes high and, as a result, the production cost tends to rise. From the viewpoint of increasing the chemical stability and mechanical strength of the wavelength conversion member 1, the softening point of the glass matrix is preferably 500° C. or more, more preferably 600° C. or more, still more preferably 700° C. or more, yet still more preferably 800° C. or more, and particularly preferably 850° C. or more. Examples of such a glass include borosilicate-based glasses. Alternatively, from the viewpoint of inexpensively producing the wavelength conversion member 1, the softening point of the glass matrix is preferably 550° C. or less, more preferably 530° or less, still more preferably 500° C. or less, yet still more preferably 480° C. or less, and particularly preferably 460° C. or less. Examples of such a glass include tin-phosphate-based glasses, bismuthate-based glasses, and tellurite-based glasses.

No particular limitation is placed on the type of the phosphor so long as it can emit fluorescence upon incidence of excitation light. A specific example of the type of the phosphor is one or more selected from the group consisting of oxide phosphor, nitride phosphor, oxynitride phosphor, chloride phosphor, oxychloride phosphor, sulfide phosphor, oxysulfide phosphor, halide phosphor, chalcogenide phosphor, aluminate phosphor, halophosphoric acid chloride phosphor, and garnet-based compound phosphor. In using a blue light as the excitation light, for example, a phosphor capable of emitting a green light, a yellow light or a red light as fluorescence can be used.

The average particle diameter of the phosphor powder is preferably 1 μm to 50 μm and more preferably 5 μm to 25 μm. If the average particle diameter of the phosphor powder is too small, the luminescence intensity may decrease. On the other hand, if the average particle diameter of the phosphor powder is too large, the luminescent color may be uneven.

The content of the phosphor powder in the wavelength conversion member 1 is preferably not less than 1% by volume, more preferably not less than 1.5% by volume, particularly preferably 2% by volume, preferably not more than 70% by volume, more preferably not more than 50% by volume, and particularly preferably not more than 30% by volume. If the content of the phosphor powder is too small, it is necessary to increase the thickness of the wavelength conversion member 1 in order to obtain a desired luminescent color. This results in increased internal scattering of the wavelength conversion member 1, which may decrease the light extraction efficiency. On the other hand, if the content of the phosphor powder is too large, it is necessary to decrease the thickness of the wavelength conversion member 1 in order to obtain the desired luminescent color, which may decrease the mechanical strength of the wavelength conversion member 1.

The thickness of the wavelength conversion member 1 is preferably not less than 0.01 mm, more preferably not less than 0.03 mm, still more preferably not less than 0.05 mm, yet still more preferably not less than 0.075 mm, particularly preferably not less than 0.08 mm, preferably not more than 1 mm, more preferably not more than 0.5 mm, even more preferably not more than 0.35 mm, still more preferably not more than 0.3 mm, yet still more preferably not more than 0.25 mm, even yet still more preferably not more than 0.15 mm, and particularly preferably not more than 0.12 mm. If the thickness of the wavelength conversion member 1 is too large, scattering and absorption of light in the wavelength conversion member 1 may be too much, so that the light extraction efficiency may be low. If the thickness of the wavelength conversion member 1 is too small, sufficient luminescence intensity may be less likely to be achieved. In addition, the mechanical strength of the wavelength conversion member 1 may be insufficient.

The refractive index (nd) of the wavelength conversion member 1 is preferably not less than 1.40, more preferably not less than 1.45, and still more preferably not less than 1.50, preferably not more than 1.90, more preferably not more than 1.80, and still more preferably not more than 1.70. If the refractive index of the wavelength conversion member 1 is too high, the refractive index difference between the wavelength conversion member 1 and the medium on the light exit side thereof (for example, an air layer (nd=1.0)) is large, so that total reflection is likely to occur on the light exit surface 1b and the light extraction efficiency may be low. If the refractive index of the wavelength conversion member 1 is too low, the refractive index difference from the light-emitting element (for example, a flip-chip mounted LED whose light exit surface is made of sapphire (nd=1.76)) becomes large. Therefore, even if an adhesive layer is provided between the wavelength conversion member 1 and the light-emitting element to adjust the refractive index difference by means of the adhesive layer, the refractive index difference between the light-emitting element and the adhesive layer and the refractive index difference between the adhesive layer and the wavelength conversion member 1 become large, so that the light extraction efficiency at each interface may be low.

An antireflection film may be provided on the light exit surface 1b of the wavelength conversion member 1. By doing so, the decrease in light extraction efficiency that will occur due to a refractive index difference between the wavelength conversion member 1 and the air during emission of fluorescence or excitation light through the light exit surface 1b can be reduced. As an example of the antireflection film, a single-layer or multi-layer dielectric film made of SiO₂, Al₂O₃, TiO₂, Nb₂O₅ or Ta₂O₅ can be cited.

An antireflection film may be provided on the light entrance surface 1a of the wavelength conversion member 1. By doing so, the decrease in the incidence efficiency of excitation light that will occur due to a refractive index difference between the adhesive layer and the wavelength conversion member 1 during incidence of excitation light into the wavelength conversion member 1 can be reduced.

When the wavelength conversion member 1 is made of a phosphor glass, the antireflection film is generally designed in consideration of the refractive index of the glass matrix in the wavelength conversion member 1. If in this case the phosphor powder is exposed on the light exit surface 1b of the wavelength conversion member 1, the antireflection film formed on the phosphor powder portions does not have a suitable film design because the phosphor powder has a relatively high refractive index, so that a sufficient antireflection function may not be achieved. To avoid this, it is preferred that a glass layer (a phosphor powder-free glass layer) be provided on the light exit surface 1b of the wavelength conversion member 1 to forma coating over the exposed phosphor powder. By doing so, the refractive index of the light exit surface 1b of the wavelength conversion member 1 is made uniform, so that the effect of the antireflection film can be increased. Preferably, a glass layer is also provided on the light entrance surface 1a of the wavelength conversion member 1 for the purpose of increasing the antireflection effect as just described.

The glass making the glass layer is preferably the same material as the glass making the glass matrix in the wavelength conversion member 1. By doing so, there is no refractive index difference between the glass matrix and the glass layer in the wavelength conversion member 1, so that the light reflection loss at both the interfaces can be reduced. In the case of providing the glass layer, it is preferred that the surface roughness of the glass layer should meet the above-described range of surface roughness Raₒᵤₜ. The thickness of the glass layer is preferably 0.003 to 0.1 mm, more preferably 0.005 to 0.03 mm, and particularly preferably 0.01 to 0.02 mm. If the thickness of the glass layer is too small, the exposed phosphor powder may not sufficiently be coated. On the other hand, if the thickness of the glass layer is too large, excitation light and fluorescence may be absorbed by the glass layer to decrease the luminous efficiency.

The wavelength conversion member 1 may be made of, except for a phosphor glass, a ceramic, such as a YAG ceramic, or may be formed so that a phosphor powder is dispersed in a resin.

The wavelength conversion member 1 can be produced in the following manner. First, a plate-like wavelength conversion member precursor is produced. The wavelength conversion member precursor can be produced, for example, by cutting a sintered body of a mixture of a phosphor powder and a glass powder. Next, both the principal surfaces of the wavelength conversion member precursor, i.e., a light entrance surface and a light exit surface, are polished to reach their respective desired surface roughnesses, thus obtaining a wavelength conversion member 1. In doing so, the type of polishing pad and the type of polishing grains are appropriately selected to adjust the surface roughnesses of both the principal surfaces of the wavelength conversion member 1. Both the principal surfaces of the wavelength conversion member precursor may be concurrently polished or may be polished one surface after the other (i.e., the light entrance surface may be first polished and then the light exit surface polished or the light exit surface may be first polished and then the light entrance surface polished). Examples of the polishing method include: a method of lapping both the surfaces of the wavelength conversion member 1 with a double-sided polishing machine and then polishing the light entrance surface with a single-sided polishing machine; and a method of polishing the light entrance surface and light exit surface of the wavelength conversion member 1 one surface after the other with a single-sided polishing machine using different types of polishing grains.

FIG. 2 is a schematic cross-sectional view showing a light emitting device according to an embodiment of the present invention. The light emitting device 10 is formed so that the wavelength conversion member 1 and a light-emitting element 2 are bonded together by an adhesive layer 3. In this embodiment, the light-emitting element 2 is placed on a substrate 4. Furthermore, a reflective layer 5 is disposed around the wavelength conversion member 1, the light-emitting element 2, and the adhesive layer 3. By disposing the reflective layer 5, excitation light and fluorescence can be reflected thereon and prevented from leaking outside, so that the light extraction efficiency can be increased. The light-emitting element 2 has, in plan view, substantially the same shape and area as the wavelength conversion member 1. However, the wavelength conversion member 1 and the light-emitting element 2 may have different shapes and areas. For example, with a plurality of light-emitting elements 2 placed alongside each other, a single wavelength conversion member 1 may be bonded to the plurality of light-emitting elements 2 to cover them.

Examples of the light-emitting element 2 include light sources capable of emitting a blue light, such as an LED light source and an LD light source. Examples of the adhesive forming the adhesive layer 3 include silicone resin-based adhesives, epoxy resin-based adhesives, vinyl resin-based adhesives, and acrylic resin-based adhesives. The adhesive forming the adhesive layer 3 preferably has a refractive index approximating that of the wavelength conversion member 1. By doing so, excitation light emitted from the light-emitting element 2 can be efficiently injected into the wavelength conversion member 1. Examples of the substrate 4 that can be used include white LTCCs (low temperature co-fired ceramics) capable of efficiently reflecting light beams emitted from the light-emitting element 2. A specific example of the white LTCC is a sintered body of an inorganic powder, such as aluminum oxide, titanium oxide or niobium oxide, and a glass powder. Alternatively, a ceramic substrate made of aluminum oxide, aluminum nitride or so on can also be used. Examples of the material for the reflective layer 6 that can be used include resin compositions and glass ceramics. An example of the resin composition that can be used is a mixture of a resin and a ceramic powder or a glass powder. The glass ceramics include LTCCs. Materials for the glass ceramic that can be used include: a mixed powder of a glass powder and a ceramic powder; and a crystallizable glass powder.

### EXAMPLES

The wavelength conversion member according to the present invention will be described below in more detail with reference to examples, but the present invention is not limited to the following examples.

Table 1 shows Examples 1 and 2 and Comparative Examples 1 to 3.

TABLE 1

| | Example | | Comparative Example | | |
|---|---|---|---|---|---|
| | 1 | 2 | 1 | 2 | 3 |
| Light exit surface Raₒᵤₜ (μm) | 0.10 | 0.20 | 0.28 | 0.30 | 0.04 |
| Light entrance surface Raᵢₙ (μm) | 0.02 | 0.04 | 0.20 | 0.02 | 0.21 |
| Raₒᵤₜ − Raᵢₙ (μm) | 0.08 | 0.16 | 0.08 | 0.28 | −0.17 |
| Relative luminous flux | 1.00 | 0.99 | 0.95 | 0.95 | 0.94 |

A borosilicate-based glass powder (average particle diameter D₅₀: 2 μm, softening point: 850° C.) and a YAG phosphor powder (average particle diameter D₅₀: 15 μm) were mixed to obtain a mixed powder. The content of the YAG phosphor powder in the mixed powder was 8.3% by volume. The mixed powder was pressed into a shape in a mold and fired near the softening point, thus obtaining a sintered body. The obtained sintered body was cut into a 30 mm×30 mm×0.3 mm plate-like wavelength conversion member precursor. The wavelength conversion member precursor was polished one surface after the other with a single-sided polishing machine using different types of polishing grains from surface to surface so that a light entrance surface and a light exit surface can have their respective desired surface roughnesses, thus obtaining a wavelength conversion member. The obtained wavelength conversion member was cut into an external size of 1 mm×1 mm, thus obtaining a small piece of wavelength conversion member.

The obtained small piece of wavelength conversion member was measured in terms of luminous flux in the following manner. A silicone resin was applied to a surface of an LED chip with an excitation wavelength of 450 nm, the small piece of wavelength conversion member was bonded to the LED chip with the silicone resin, and a highly reflective silicone resin was applied to outer peripheries of the LED chip and the small piece of wavelength conversion member, thus obtaining a measurement sample. Light emitted from the light exit surface of the small piece of wavelength conversion member was taken into an integrating sphere, guided to a spectrometer calibrated by a reference light source, and measured in terms of spectral energy distribution with the spectrometer. A luminous flux was calculated from the obtained spectral energy distribution. Note that the luminous fluxes in Table 1 are expressed as values relative to the luminous flux in Example 1 assumed to be 1.

As shown in Table 1, the wavelength conversion members of Examples 1 and 2 had a relative luminous flux of 0.99 or more, whereas the wavelength conversion members of Comparative Examples 1 to 3 had an inferior relative luminous flux of 0.95 or less.

### REFERENCE SIGNS LIST

2 wavelength conversion member

1a light entrance surface

1b light exit surface

2 light-emitting element

3 adhesive layer

10 light emitting device

1. A wavelength conversion member containing a phosphor and having a plate-like shape,
the wavelength conversion member including a light entrance surface and a light exit surface opposite to the light entrance surface,
wherein Raᵢₙ is 0.01 to 0.05 μm and Raₒᵤₜ−Raᵢₙ is 0.01 to 0.2 μm where Rain represents a surface roughness of the light entrance surface and Raₒᵤₜ represents a surface roughness of the light exit surface.

2. The wavelength conversion member according to claim 1, wherein the surface roughness Raₒᵤₜ of the light exit surface is 0.06 μm or more.

3. The wavelength conversion member according to claim 1, being formed so that powder of the phosphor is dispersed in a glass matrix.

4. The wavelength conversion member according to claim 1, having a thickness of 0.01 to 1 mm.

5. A light emitting device comprising:
the wavelength conversion member according to claim 1; and
a light-emitting element capable of irradiating the wavelength conversion member with excitation light.

6. The light emitting device according to claim 5, wherein the light entrance surface of the wavelength conversion member and the light-emitting element are bonded together by an adhesive layer.

7. The light-emitting element according to claim 5, wherein a reflective layer is disposed around the wavelength conversion member and the light-emitting element.
